(19) United States
(12) Patent Application Publication
(10) Pub. No.: US 2007/0172597 A1
(43) Pub. Date: Jul. 26, 2007

(54) Automatic spraying method for flux of wave solder oven

(75) Inventor: Kuo-Hsin Tsai, Taoyuan Hsien (TW)

Correspondence Address: HDSL, 4331 STEVENS BATTLE LANE, FAIRFAX, VA, 22033, US

(73) Assignee: Delta electronics, Inc.

(21) Appl. No.: 11/336,792

(22) Filed: Jan. 23, 2006

(51) Int. Cl. C23C 16/52; B05D 5/12; B05D 7/00

(52) U.S. Cl. 427/421.1; 427/8; 427/96.1

(57) ABSTRACT

An automatic spraying method is used for spraying flux of wave solder oven. A first optical sensor senses the width of a printed circuit board (PCB) to obtain a first set parameter, and the first set parameter is stored in an address designated by a first register. A second optical sensor senses the length, the width and the spraying direction of the PCB to obtain a second set parameter, and the second set parameter is stored in an address designated by a second register. The control parameters such as initial spraying position, spraying area and spraying speed are calculated with reference to the first and the second sets parameters. The flux is sprayed on the PCB by a spray gun according to the control parameters.

### BACKGROUND OF THE INVENTION

1. Field of the Invention

The present invention relates to an automatic spraying method used for flux of wave solder oven, especially to an automatic spraying method sensing two spray parameters for PCB of various sizes and calculating the spray area and optimal spray control.

2. Description of Prior Art

The conventional method for spraying the flux on printed circuit board (PCB) uses wave solder oven and a transmission unit. The PCB is conveyed to a processing machine and a plurality of sensors arranged in the processing machine sense the length and width of the PCB. The sensed result is used as control parameters for the spraying gun and the servo mechanism. The spraying gun sprays flux to the PCB loaded into the processing machine.

However, the above-mentioned sensor arranged in the processing machine can only be useful for PCB of a single size (single length and width) and sends the sensed result externally. When PCB of various form factors is to be processed, the position of the sensor needs adjustment for precisely sensing the length and width of the PCB. In other word, the position of the sensor needs re-adjustment when the PCB of different size is loaded. This procedure is troublesome.

### SUMMARY OF THE INVENTION

The present invention is intended to provide an automatic spraying method used for PCB of various sizes and conduct optimal spray control with parameter measurement.

Accordingly, the present invention provides an automatic spraying method for flux of wave solder oven. The wave solder oven is equipped with a first optical sensor, a second optical sensor, a spray gun unit and a convey unit. Parameters are sensed when a printed circuit board (PCB) is sent to a processing machine to calculate control parameters to drive the spray gun unit. The method comprising

performing an initialization step to return a servo mechanism of spray gun unit to origin and clear internal data of each register;

performing a first detection step to sense width of the PCB as a first set parameter;

performing a second detection step to sense length, width and spray direction of the PCB as a second set parameter;

performing a parameter reading step to calculate control parameters for matching the PCB according to the first set parameter and the second set parameter; and

performing a spray step to drive the spray gun unit according to the control parameters and to turn off the spray gun unit after flux is applied.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a schematic diagram of the processing machine according to a preferred embodiment of the present invention.

FIG. 2 shows the block diagram of automatic spraying apparatus for flux according to a preferred embodiment of the present invention.

FIG. 3 is a flowchart showing the steps of automatic spraying according to a preferred embodiment of the present invention.

### DETAILED DESCRIPTION OF THE INVENTION

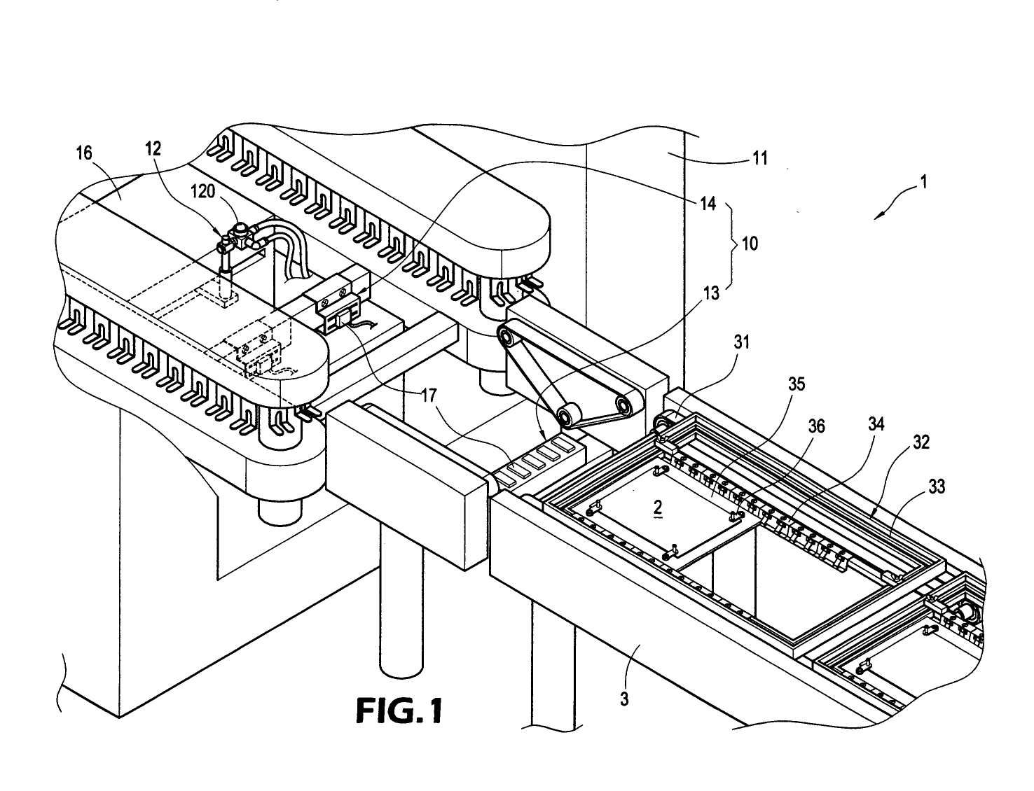

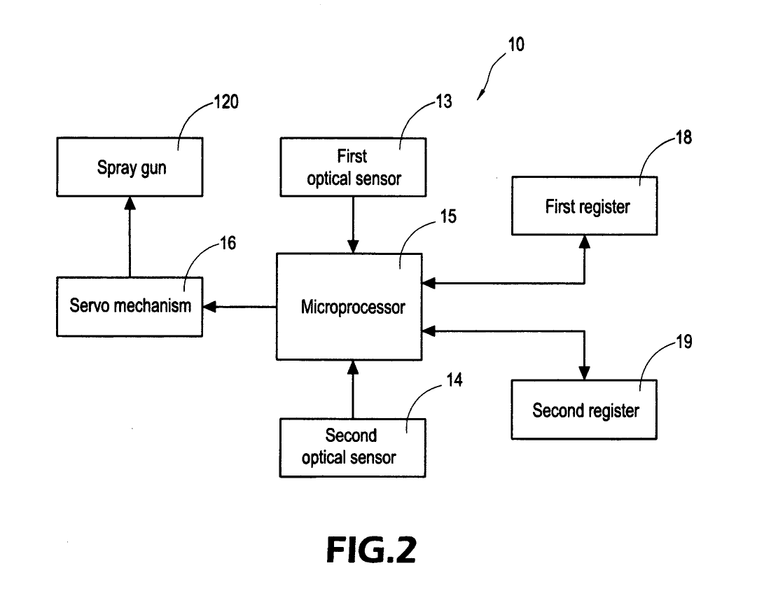

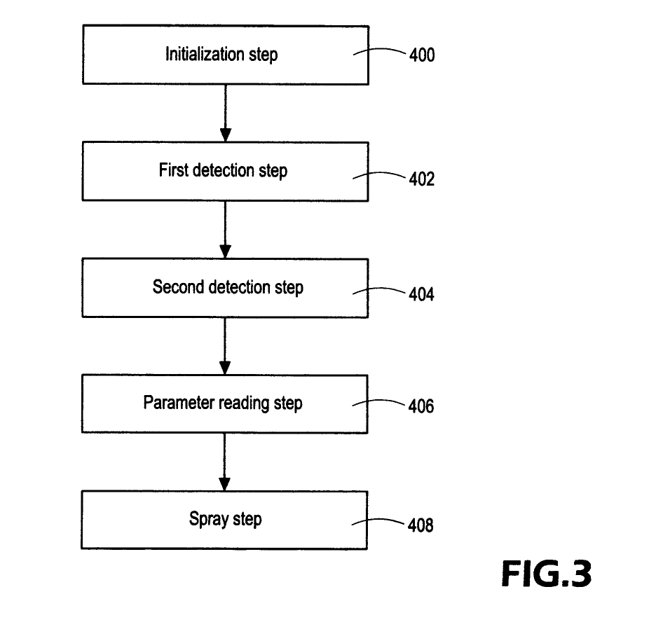

With reference to FIGS. 1 to 3, the automatic spraying apparatus for flux comprises a machine 1 with a cabinet 11, and a spray gun unit 12 and a sensor device 10 arranged in the cabinet 11. A convey unit 3 is connected to one end of the cabinet 11 for conveying the PCB to be processed to the cabinet 11 for applying the flux.

The sensor device 1 includes a first optical sensor 13, a second optical sensor 14 and a microprocessor 15. The microprocessor 15 is connected to a servo mechanism 16 of the spray gun unit 12.

The spray gun unit 12 comprises a spray gun 120 and the servo mechanism 16 for moving the spray gun 120.

The first optical sensor 13 and the second optical sensor 14 comprise a plurality of photo sensors 17 and arranged at two predetermined front positions of the spray gun unit 12 in predetermined separation. The first optical sensor 13 and the second optical sensor 14 are electrically connected to a first register 18 and a second register 19. The sensed parameters are stored in the addresses designated by the first optical sensor 13 and the second optical sensor 14 according to the order of the PCB 2 passing the first optical sensor 13 and the second optical sensor 14. The sensed parameters are used for later operation.

The wave solder oven 3 comprises at least one conveying track 31 and a plurality of tools 32 moved in the conveying track 31. The tool 32 comprises a hollow frame 33 and a plurality of racks 34 on the wall of the frame 33. The racks 34 supports a supporting plate 35 with a plurality of dampers 36 thereon to clamp PCB of various sizes and send the PCB to the machine (wave solder oven) 1.

The method for applying flux by using the automatic spraying apparatus according to the present invention comprises following steps:

In an initialization step 400, the machine 1 is started and the servo mechanism (not shown) is returned to origin. The temporary data in the first register 18 and the second register 19 are cleared. The PCB 2 to be applied with flux is clamped by tool 32 and sent sequentially into the cabinet 11.

In first detection step 402, the first optical sensor 13 detects the width of the PCB 2 sent by the tool 32 and the first optical sensor 13 sends the detection signal and temporarily stored in the address designated by the first register 18 to form a first set parameter.

After the first set parameter 13 has performed sensing operation, a second detection step 404 is performed. The second optical sensor 14 senses the PCB 2 having been sensed by the first optical sensor 13 and carried by the tool 32. The length, width and spray direction of the PCB 2 are sensed to obtain the second set parameter and the second set parameter is stored in the address designated by the second register 19.

After the first set parameter and the second set parameter are obtained, a step 406 is performed for reading parameter. The microprocessor 15 reads the first set parameter stored in the first register 18 and the second set parameter stored in the second register 19 and calculates control parameters for matching the spraying operation of the PCB 2. The control parameters comprises spray initial position, initial spray time, spray speed and spray width.

After parameters are read, a step 408 is performed for flux spray. The control parameters thus calculated are input to the spray gun unit 12 and the spray gun unit 12 drives the servo mechanism 16 . The servo mechanism 16 controls the spray gun 12 for applying flux to the PCB 2 and turns off the spray gun 12 after the flux applying is finished. The servo mechanism 16 waits for next control parameters for controlling the flux applying of next PCB.

In the second detection step 404, the detection parameter for spray direction further comprises moving direction of the PCB 2, the amount of PCBs clamped by the same tool 32, a spray initial position, a spray initial direction and sequence (when more than one PCB is clamped by the tool 32). When two PCBs are clamped by the tool 32 for spray operation, the second optical sensor 14 will sense relevant positions, moving direction, amount and optimal initial position for the two PCB 2. For example, the optimal initial position for the two PCB 2 can start from outer sides of the PCBs 2 and toward inner sides to prevent from spraying flux to adjacent PCB.

Moreover, in the step 406 for reading parameter, the spray time parameter of the spray gun 120 is calculated according to the distance between the second optical sensor 14 and the spray gun 120 and the speed of the convey unit 3.

The first set parameter and the second set parameter sensed by the first optical sensor 13 and the second optical sensor 14 for the PCB are stored in the first register 18 and the second register 19 sequentially. Therefore, two sets of parameters for the PCB can be correctly obtained.

After the PCB 2 is sent to the machine 1, the first set parameter 13 and the second optical sensor 14 sense width, length and spray direction information to obtain the two sets of parameters. Therefore the spray initial position, the spray start time, spray speed and spray width parameters can be calculated and can be used as control parameters for the spray gun unit 12. The flux spraying operation can be performed to PCB of various sizes for automatic parameter sensing. The conventional problem of adjusting sensor position and efficiency problem can be solved.

Moreover, the second optical sensor 14 can sense the spray direction of the PCB 2 and the amount of PCB clamped by the tool 32. Therefore, the PCBs with smaller sizes can be applied with flux at the same time. The efficiency and yield can be enhanced.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. An automatic spraying method for flux of wave solder oven, the method being used for a wave solder oven equipped with a first optical sensor, a second optical sensor, a spray gun unit and a convey unit, parameters being sensed when a printed circuit board (PCB) is sent to a processing machine to calculate control parameters to drive the spray gun unit; the method comprising:
performing an initialization step to return a servo mechanism of spray gun unit to origin and clear internal data of each register;
performing a first detection step to sense width of the PCB as a first set parameter;
performing a second detection step to sense length, width and spray direction of the PCB as a second set parameter;
performing a parameter reading step to calculate control parameters for matching the PCB according to the first set parameter and the second set parameter;
performing a spray step to drive the spray gun unit according to the control parameters and to turn off the spray gun unit after flux is applied.

2. The automatic spraying method as in claim 1, further comprising:
in the first detection step, the first optical sensor senses width of the PCB sent through the convey unit to obtain the first set parameter.

3. The automatic spraying method as in claim 2, further comprising:
storing the first set parameter sensed by the first optical sensor to a register.

4. The automatic spraying method as in claim 1, further comprising:
in the second detection step, the second optical sensor senses length, width and spray direction of the PCB sent through the convey unit to obtain the second set parameter.

5. The automatic spraying method as in claim 4, further comprising:
storing the second set parameter sensed by the second optical sensor to a register.

6. The automatic spraying method as in claim 4, wherein the spray direction parameter comprises moving direction of the PCB, amount of PCBs carried in the same batch by the convey unit, a spray initial position, a spray initial direction and sequence when more than one PCB is sent.

7. The automatic spraying method as in claim 1, wherein the first set parameter and the second set parameter sensed by the first optical sensor and the second optical sensor for the PCB are stored in the registers sequentially, whereby two sets of parameters for the PCB can be correctly obtained.

8. The automatic spraying method as in claim 1, wherein in the parameter reading step, the first set parameter and the second set parameter are read through register to calculate control parameters for matching the PCB according to the first set parameter and the second set parameter.

9. The automatic spraying method as in claim 8, wherein the control parameters comprises spray initial position, initial spray time, spray speed and spray width.

10. The automatic spraying method as in claim 1, further comprising
providing an automatic spraying apparatus for flux, the automatic spraying apparatus comprising
a microprocessor;
a first optical sensor electrically connected to the microprocessor;
a first register electrically connected to the microprocessor and storing the first set parameter sensed by the first optical sensor for the reading of the microprocessor;
a second optical sensor electrically connected to the microprocessor;
a second register electrically connected to the microprocessor and storing the second set parameter sensed by the second optical sensor for the reading of the microprocessor.
